(19) United States
(12) Patent Application Publication
(10) Pub. No.: US 2024/0349513 A1
(43) Pub. Date: Oct. 17, 2024

(54) SEMICONDUCTOR DEVICE AND METHOD FOR FABRICATING THE SAME

(71) Applicant: SK hynix Inc., Icheon-si (KR)

(72) Inventor: Tae Jung HA, Icheon-si (KR)

(21) Appl. No.: 18/467,617

(22) Filed: Sep. 14, 2023

(30) Foreign Application Priority Data
Apr. 17, 2023 (KR) 10-2023-0050081

(51) Int. Cl. H10B 61/00

(52) U.S. Cl. CPC H10B 61/00

(57) ABSTRACT

A semiconductor device includes: a first contact plug disposed over the substrate; two or more insulating patterns disposed on a side surface of the first contact plug and sequentially along a direction away from the first contact plug; and a memory pattern connected to the first contact plug, wherein an upper surface of the first contact plug and upper surfaces of the insulating patterns form an inclined surface whose height decreases as a distance from a center of the first contact plug increases, the inclined surface includes a first inclined surface disposed on a first side of the center of the first contact plug and a second inclined surface disposed on second side of the center of the first contact plug, the second side opposite to the first side, and the memory pattern has a lower surface in contact with the first inclined surface.

### PRIORITY CLAIM AND CROSS-REFERENCE TO RELATED APPLICATION

This patent document claims priority under 35 U.S.C. § 119 to Korean Patent Application No. 10-2023-0050081 filed on Apr. 17, 2023, which is incorporated herein by reference in its entirety.

### TECHNICAL FIELD

This patent document relates to a semiconductor technology, and more particularly, to a semiconductor device including a plurality of memory cells, and a method for fabricating the semiconductor device.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

In an embodiment, a semiconductor device may include: a substrate; a first contact plug disposed over the substrate; two or more insulating patterns disposed on a side surface of the first contact plug and disposed sequentially along a direction away from the first contact plug; and a memory pattern disposed over the first contact plug and connected to the first contact plug, wherein an upper surface of the first contact plug and upper surfaces of the insulating patterns form an inclined surface whose height decreases as a distance from a center of the first contact plug increases, the inclined surface includes a first inclined surface disposed on a first side of the center of the first contact plug and a second inclined surface disposed on second side of the center of the first contact plug, the second side opposite to the first side, and the memory pattern has a lower surface in contact with the first inclined surface.

In an embodiment, a method for fabricating a semiconductor device, may include: forming a first contact plug and first to Nth insulating patterns (where N is a natural number of 2 or more) sequentially disposed from the first contact plug and surrounding a side surface of the first contact plug, where an upper surface of the first contact plug and upper surfaces of the first to Nth insulating patterns form an inclined surface whose height decreases as a distance from a center of the first contact plug increases, and the inclined surface includes a first inclined surface disposed on one side of the center of the first contact plug and a second inclined surface disposed on the other side of the center of the first contact plug; forming a memory layer such that a portion of the memory layer has a first thickness over the first inclined surface and another portion of the memory layer has a second thickness smaller than the first thickness over the second inclined surface; and removing the another portion of the memory layer having the second thickness and providing a memory pattern connected to the first contact plug over the first contact plug.

### BRIEF DESCRIPTION OF THE DRAWINGS

FIGS. 1A to 5B are views illustrating a semiconductor device according to an embodiment of the present disclosure, and a method for fabricating the same.

FIG. 6 is view illustrating a memory layer according to an embodiment of the present disclosure.

FIG. 7 is a view illustrating a memory layer according to another embodiment of the present disclosure.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

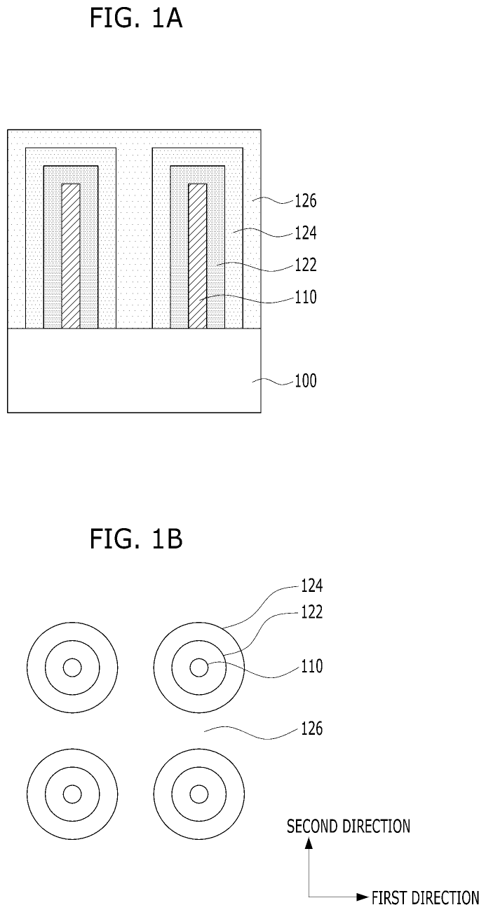

FIGS. 1A to 5B are views illustrating a semiconductor device according to one example for implementing an embodiment of the present disclosure, and a method for fabricating the same. FIGS. 1A, 2A, 3A, 4A, and 5A are cross-sectional views, and FIGS. 1B, 2B, 3B, 4B, and 5B are plan views. FIGS. 1A, 2A, 3A, 4A, and 5A show cross-sections along a first direction of FIGS. 1B, 2B, 3B, 4B, and 5B, respectively.

First, the manufacturing method will be described.

Referring to FIGS. 1A and 1B, a substrate 100 may be provided.

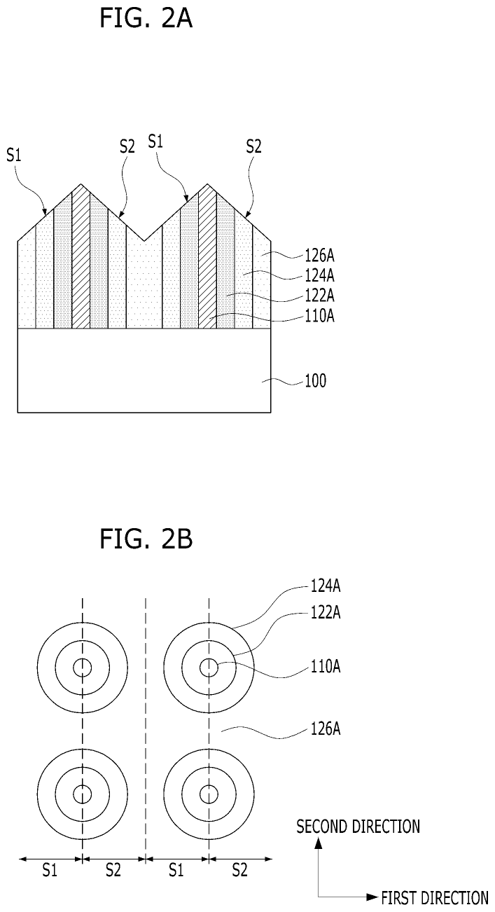

The substrate 100 may include a semiconductor material such as silicon, and a predetermined lower structure (not shown) may be formed in the substrate 100. As an example, the substrate 100 may include an element that is electrically connected to a first contact plug (see 110A in FIGS. 2A and 2B) to be described later and transfers a required voltage or current to the first contact plug, for example, a conductive line such as a word line or a switching element such as a transistor.

Subsequently, an initial first contact plug 110 and initial first to third insulating patterns 122, 124, and 126 may be formed over the substrate 100.

The initial first contact plug 110 may have a pillar shape. In the present embodiment, the initial first contact plug 110 has a circular shape in a plan view, but the present disclosure is not limited thereto. For example, the planar shape of the initial first contact plug 110 may have various shapes such as a square shape or others. A plurality of initial first contact plugs 110 may be arranged in a matrix form along first and second directions. In the present embodiment, the initial first contact plugs 110 are arranged in a 2*2 shape, but the present disclosure is not limited thereto, and the number or arrangement of the initial first contact plugs 110 may be variously modified. The initial first contact plug 110 may be formed by depositing a conductive material to a desired thickness and selectively etching the conductive material.

The initial first insulating pattern 122 may be conformally formed over the initial first contact plug 110 along the surface of the initial first contact plug 110, that is, along the upper and side surfaces of the initial first contact plug 110. Accordingly, the initial first insulating pattern 122 may have a pillar shape surrounding the surface of the initial first contact plug 110. The initial second insulating pattern 124 may be conformally formed over the initial first insulating pattern 122 along the surface of the initial first insulating pattern 122. Accordingly, the initial second insulating pattern 124 may have a pillar shape surrounding the surface of the initial first insulating pattern 122. The initial third insulating pattern 126 may be conformally formed along the surface of the initial second insulating pattern 124, and may have a thickness sufficient to fill a space between the initial second insulating patterns 124 having a pillar shape. Each of the initial first to third insulating patterns 122, 124, and 126 may be formed by a deposition method such as an ALD (Atomic Layer Deposition) process. In the specific example as illustrated in FIG. 1A, three insulating patterns 122, 124, and 126 are shown and described, but the present disclosure is not limited thereto, and the number of insulating patterns may be variously modified to include two or more insulating patterns. Thus, the initial first to Nth insulating patterns (where N is a natural number of 2 or more) may be sequentially formed on the initial first contact plug 110. The initial first to N−1th insulating patterns among the initial first to Nth insulating patterns may have pillar shapes surrounding the surfaces of the initial first contact plug 110 and the initial first to N−2th insulating patterns, respectively. The initial Nth insulating pattern may be formed to a thickness sufficiently filling a space between the initial N−1th insulating patterns while surrounding the surface of the initial N−1th insulating pattern.

Here, the relationship between the initial first contact plug 110 and the initial first to third insulating patterns 122, 124, and 126 will be described in detail as follows. The initial first contact plug 110 may include a material having the lowest etch rate during a blanket etching process (refer to FIG. 2), which will be described later. The initial first to third insulating patterns 122, 124, and 126 may include materials having etch rates higher than an etching rate of the initial first contact plug 110 during the blanket etching process, and the etch rates of the initial first to third insulating patterns 122, 124, and 126 may increase as the distance from the initial first contact plug 110 increases. During the blanket etching process, the etch rate of the initial first insulating pattern 122 may be greater than the etch rate of the initial first contact plug 110, the etch rate of the initial second insulating pattern 124 may be greater than the etch rate of the initial first insulating pattern 122, and the etch rate of the third insulating pattern 126 may be greater than the etch rate of the initial second insulating pattern 124. Assuming that the initial first to Nth insulating patterns exist, the etch rate of the initial t-th insulating pattern (where t is a natural number of 2 or more and N or less) among the initial first to Nth insulating patterns may be greater than the etch rate of the initial t−1th insulating pattern.

The conductive material for forming the initial first contact plug 110 and the insulating materials for forming the initial first to third insulating patterns 122, 124, and 126 may be determined as one of various materials without being limited to a particular material, as long as the above relationship regarding the etch rates is satisfied. For example, the initial first contact plug 110 may include a conductive material such as carbon, a metal, an alloy, or a conductive metal compound, and the initial first to third insulating patterns 122, 124, and 126 may include an insulating material such as silicon oxide, silicon nitride, silicon oxynitride, or a combination thereof. Here, the insulating material may further include impurities such as carbon or boron. The etch rate may vary depending on the type of material, but may also vary depending on the composition ratio of constituent elements in the same material. For example, the initial first insulating pattern 122, the initial second insulating pattern 124, and the initial third insulating pattern 126 may be formed of or include different insulating materials from one another. In some other implementations, at least two of the initial first insulating pattern 122, the initial second insulating pattern 124, and the initial third insulating pattern 126 may be formed of or include the same material with different composition ratios of the same material. For example, at least two of the initial first insulating pattern 122, the initial second insulating pattern 124, and the initial third insulating pattern 126 may include a material including the same constituent elements, but the composition ratio of the constituent elements of one of the same constituent elements may be different from each other. In some implementations, the etch rate may vary depending on the type or content of the impurities.

In an example, the initial first contact plug 110 may include a metal having a lower etch rate than silicon oxide, and the initial first to third insulating patterns 122, 124, and 126 may include silicon oxide. Here, the silicon contents of the initial first to third insulating patterns 122, 124, and 126 may be different from one another. For example, the initial first insulating pattern 122 may have the lowest silicon content, the initial third insulating pattern 126 may have the highest silicon content, and the initial second insulating pattern 124 may have a silicon content between the silicon content of the initial first insulating pattern 122 and the silicon content of the third insulating pattern 126. This may be because, in general, the higher the silicon content in silicon oxide, the higher the etch rate.

Referring to FIGS. 2A and 2B, a first contact plug 110A and first to third insulating patterns 122A, 124A, and 126A may be formed by performing a blanket etching process on the process result of FIGS. 1A and 1B.

As described above, the etch rate of the initial first contact plug 110 may be minimal as compared to the etch rates of the first to third insulating patterns 122, 124, and 126, and the etch rates of the initial first to third insulating patterns 122, 124, and 126 may increase as the distance from the initial first contact plug 110 increases. Therefore, after the blanket etching process, the height of the first contact plug 110A may be the largest, and the heights of the first to third insulating patterns 122A, 124A, and 126A may be smaller than the height of the first contact plug 110A. Further, the heights of the first to third insulating patterns 122A, 124A, and 126A may decrease as the distance from the contact plug 110A increases. In particular, since the height of the first contact plug 110A is the highest at the center and the height of the first contact plug 110A decreases as the distance from the center increases, the upper surface of the first contact plug 110A may have a cone shape with a sharp center or a shape similar thereto. Each of the first insulating pattern 122A, the second insulating pattern 124A, and the third insulating pattern 126A may have an inclined upper surface whose height decreases as the distance from the first contact plug 110A increases. As a result, as shown, the upper surfaces of the first contact plug 110A and the first to third insulating patterns 122A, 124A, and 126A may form an inclined surface whose height gradually decreases as the distance from the center of the first contact plug 110A increases. A portion of the inclined surface, which is located on one side, for example, the left side of the center of the first contact plug 110A in the first direction, may be referred to as a first inclined surface S1, and another portion of the inclined surface, which is located on the other side, for example, the right side of the center of the first contact plug 110A in the first direction, may be referred to as a second inclined surface S2. In the implementations, the portion and another portion of the inclined surface are disposed on opposite sides of the center of the first contact plug 110A. Along a direction from left to right in the first direction, the first inclined surface S1 may have a gradually increasing height and the second inclined surface S2 may have a gradually decreasing height, and the first inclined surface S1 and the second inclined surface S2 may be alternately and repeatedly arranged. In the present embodiment, the degree of the inclination of each

of the first inclined surface S1 and the second inclined surface S2 is shown to be substantially constant, but the present disclosure is not limited thereto, and the degree of the inclination of each of the first inclined surface S1 and the second inclined surface S2 may vary depending on the location.

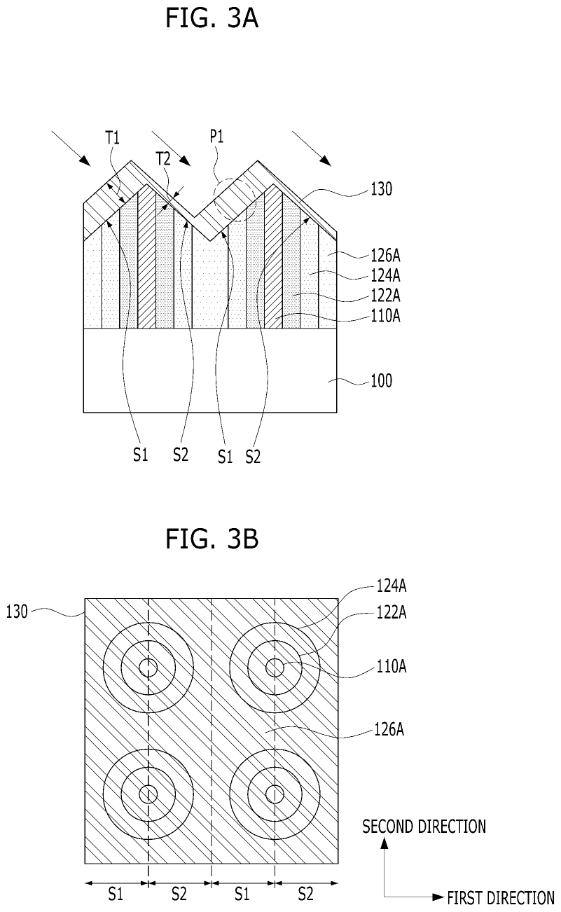

Referring to FIGS. 3A and 3B, a memory layer 130 that performs a function of storing data may be formed over the first and second inclined surfaces S1 and S2 of the first contact plug 110A and the first to third insulating patterns 122A, 124A, and 126A.

The memory layer 130 may be formed using an inclined deposition process (refer to arrow) in which the deposition is performed in a direction toward the first inclined surface S1. In this case, the memory layer 130 may be deposited thinner over the second inclined surface S2 than over the first inclined surface S1. Accordingly, the memory layer 130 may have a relatively large first thickness T1 over the first inclined surface S1 and a relatively small second thickness T2 over the second inclined surface S2. The first thickness T1 may be substantially the same as a target thickness so that the memory layer 130 can perform a data storage function. Since the memory layer 130 is formed along the first and second inclined surfaces S1 and S2, the upper and lower surfaces of the memory layer 130 may also be substantially parallel to the first and second inclined surfaces S1 and S2.

In an example, the inclined deposition may be performed in a PVD (Physical Vapor Deposition) method. In addition, the inclined deposition may be performed at an angle other than 90 degrees with respect to the upper surface of the substrate 100. For example, as illustrated, the inclined deposition may be performed at an angle of about 90 degrees with respect to the first inclined surface S1 while being performed at an angle of about 45 degrees with respect to the upper surface of the substrate 100. However, the present disclosure is not limited thereto, and the angle of the inclined deposition may be variously modified.

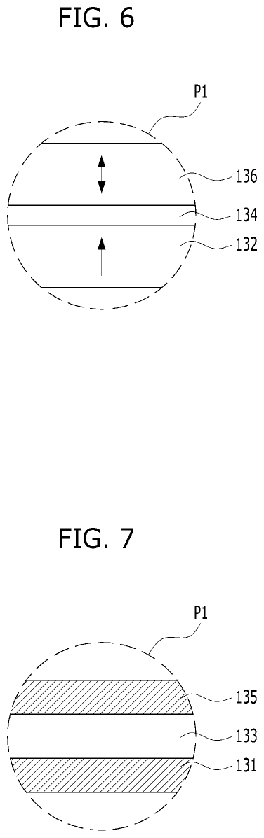

Here, the memory layer 130 may function to store data in various ways, and may have a single-layer structure or a multi-layer structure. In an example, the memory layer 130 may include a variable resistance layer that stores different data by switching between different resistance states according to a voltage or current supplied through the upper and lower ends of the memory layer 130. The variable resistance layer may have a single-layer structure or multi-layer structure including various materials used in RRAM, PRAM, FRAM, MRAM, etc., for example, a metal oxide such as a transition metal oxide or a perovskite-based material, a phase change material such as a chalcogenide-based material, a ferroelectric material, a ferromagnetic material, or the like. The memory layer 130 will be further described by way of example with reference to FIGS. 6 and 7 to be described later. When the memory layer 130 has a multi-layer structure, the thickness of each of the multiple layers for forming the memory layer 130 over the first inclined surface S1 may be greater than the thickness of each of the multiple layers for forming the memory layer 130 over the second inclined surface S2.

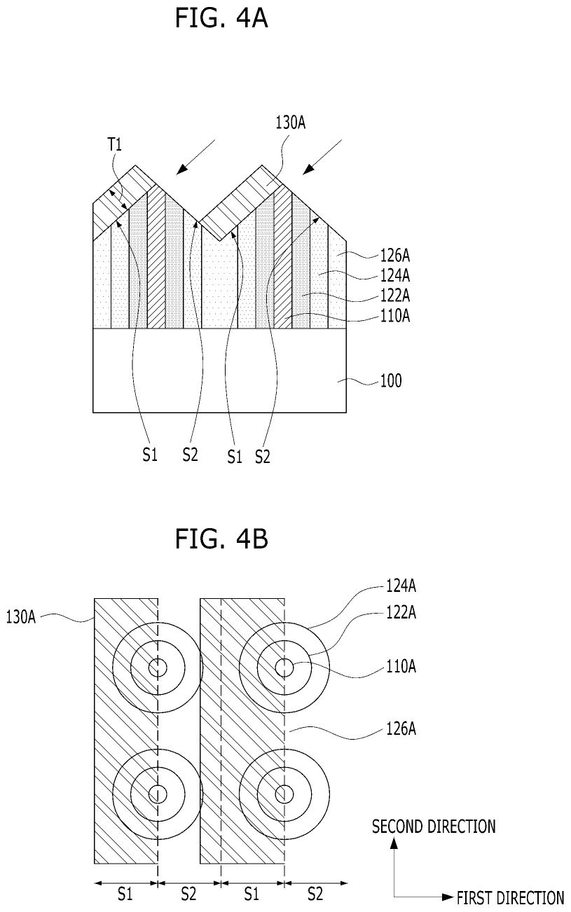

Referring to FIGS. 4A and 4B, an inclined etching process (refer to the arrow) may be performed on the memory layer 130 in a direction toward the second inclined surface S2. In this case, only the memory layer 130 over the second inclined surface S2 may be etched while the memory layer 130 over the first inclined surface S1 is substantially maintained. The inclined etching may be performed by targeting the second inclined surface S2 to expose the second inclined surface S2. As a result of the performing the inclined etching process, the memory pattern 130A over the first inclined surface S1 may be formed. Since the memory pattern 130A is positioned over the first inclined surface S1, the lower surface of the memory pattern 130A may directly contact the upper surface of the first contact plug 110A and be connected to the first contact plug 110A. In some implementations, the lower surface of the memory pattern 130A may contact one side half, for example, the left half of the upper surface of the first contact plug 110A. The lower surface of the memory pattern 130A may contact the first inclined surface S1, and the upper surface of the memory pattern 130A may be substantially parallel to the first inclined surface S1.

The memory pattern 130A may substantially maintain the first thickness T1. In the first direction, the memory pattern 130A may have one side surface, for example, a left side surface, positioned at a relatively low height, and the other side surface, for example, a right side surface, positioned at a relatively high height. The one side surface of the memory pattern 130A may overlap and contact a portion of the second inclined surface S2. Since the inclined etching is performed to expose the second inclined surface S2, the memory pattern 130A may be separated from another memory pattern 130A adjacent thereto in the first direction. In addition, the memory pattern 130A may have a line shape extending in the second direction. Accordingly, the memory pattern 130A may be commonly connected to the first contact plugs 110A arranged in the second direction.

In an example, the inclined etching may be performed using an IBE (Ion Beam Etching) method. In addition, the inclined etching may be performed at an angle other than 90 degrees with respect to the upper surface of the substrate 100. For example, as illustrated, the inclined etching may be performed at an angle of about 90 degrees with respect to the second inclined surface S2 while being performed at an angle of about 45 degrees with respect to the upper surface of the substrate 100. Furthermore, the direction of the inclined etching and the direction of the inclined deposition may form a predetermined angle, for example, about 90 degrees. However, the present disclosure is not limited thereto, and an angle of the inclined etching may be variously modified.

In the case of using this inclined etching, the memory pattern 130A may be formed by removing a portion of the memory layer 130, which has a relatively small thickness over the second inclined surface S2. Therefore, the margin of the etching process may be increased. In addition, since it is facilitated to separate the memory pattern 130A from the adjacent memory pattern 130A in the first direction, various defects that occur when the memory patterns 130A are not properly separated may be prevented and/or reduced.

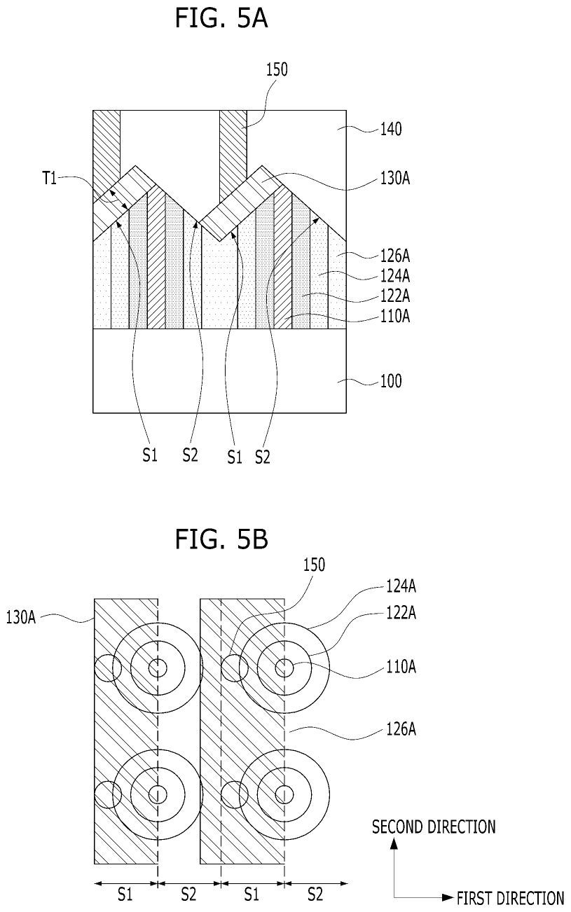

Referring to FIGS. 5A and 5B, an interlayer insulating layer 140 covering the process result of FIGS. 4A and 4B may be formed. The interlayer insulating layer 140 may include various insulating materials such as silicon oxide or silicon nitride.

Subsequently, a second contact plug 150 may be formed through the interlayer insulating layer 140 and connected to the memory pattern 130A.

The second contact plug 150 may be formed by selectively etching the interlayer insulating layer 140 to form a hole exposing the upper surface of the memory pattern 130A, depositing a conductive material having a thickness sufficient to fill the hole, and performing a planarization process, for example, a CMP (Chemical Mechanical Polishing) process until the upper surface of the interlayer insulating layer 140 is exposed.

The second contact plug 150 may have a pillar shape. The second contact plug 150 may have an upper surface planarized with the upper surface of the interlayer insulating layer 140. Thus, the upper surface of the second contact plug 150 may be substantially parallel to the upper surface of the substrate 100. On the other hand, since the upper surface of the memory pattern 130A forms an inclined surface, the lower surface of the second contact plug 150 may come into contact with the upper surface of the memory pattern 130A to form an inclined surface. In the present embodiment, the second contact plug 150 may have a circular shape in a plan view, but the present disclosure is not limited thereto. For example, the second contact plug 150 may have various forms such as a square shape or others, without being limited to the circular shape.

A plurality of second contact plugs 150 may be arranged in a matrix form along the first and second directions. For example, the second contact plugs 150 may be arranged in a 2*2 shape having two rows and two columns. In addition, the plurality of second contact plugs 150 may correspond to the plurality of first contact plugs 110A, and may be formed at positions respectively adjacent to the plurality of first contact plugs 110A in a plan view. Since the first contact plug 110A contacts the end of the lower surface extending from the other side of the memory pattern 130A, for example, the right side, the second contact plug 150 in contact with the upper surface of the memory pattern 130A may not overlap the contact plug 110A in a plan view. Accordingly, in a plan view, the second contact plug 150 may be spaced apart from the corresponding first contact plug 110A by a predetermined distance. For example, as illustrated, the second contact plug 150 may be disposed on the left side of the corresponding first contact plug 110A and spaced apart from the first contact plug 110A. In addition, since the memory pattern 130A has a line shape extending in the second direction, the second contact plugs 150 arranged in the second direction may be commonly connected to the memory pattern 130A. Even if the second contact plugs 150 are arranged in this way, the memory pattern 130A between the selected first contact plug 110A and the selected second contact plug 150 may be driven according to the voltage or current applied through the selected first contact plug 110A and the selected second contact plug 150. As a result, by providing voltage or current through the selected first and second contact plugs 110 and 150, the corresponding memory pattern 130A can be driven normally.

Subsequently, although not shown, a conductive line, for example, a bit line may be formed over the interlayer insulating layer 140 and the second contact plug 150 to be electrically connected to the second contact plug 150 to transfer a required voltage or current to the second contact plug 150.

As a result, a semiconductor device as shown in FIGS. 5A and 5B may be fabricated.

Referring back to FIGS. 5A and 5B, the semiconductor device according to the present embodiment may include the substrate 100, the first contact plug 110A disposed over the substrate 100, the first to third insulating patterns 122A, 124A, and 126A sequentially disposed from the first contact plug 110A while surrounding the side surface of the first contact plug 110A, the memory pattern 130A connected to the first contact plug 110A over the first contact plug 110A, and the second contact plug 150 connected to the memory pattern 130A over the memory pattern 130A.

Here, the upper surfaces of the first contact plug 110A and the first to third insulating patterns 122A, 124A, and 126A may form an inclined surface with a height decreasing from the center of the first contact plug 110A. The inclined surface on one side, for example, the left side of the center of the first contact plug 110A in the first direction may be referred to as the first inclined surface S1, and the inclined surface on the other side, for example, the right side of the center of the first contact plug 110A in the first direction may be referred to as the second inclined surface S2. The memory pattern 130A may be formed over the first inclined surface S1 to have a lower surface contacting the first inclined surface S1. Among both side surfaces of the memory pattern 130A, one side surface having a low height, for example, the left side surface may contact the second inclined surface S2. Except for this left side surface, the memory pattern 130A may not exist over the second inclined surface S2. The memory pattern 130A may have a substantially constant thickness over the first inclined surface S1, for example, the first thickness T1. Accordingly, the memory pattern 130A may also include an inclined upper surface substantially parallel to the first inclined surface S1.

The second contact plug 150 may have a lower surface forming an inclined surface by contacting the upper surface of the memory pattern 130A as described above.

In such a semiconductor device, the memory pattern 130A may store different data according to a voltage or current supplied through the first and second contact plugs 110A and 150. For example, when the memory pattern 130A includes a variable resistance layer, the memory pattern 130A may store different data by switching between different resistance states.

Since the components of the semiconductor device have been described in detail in the process of describing the fabricating method, further description of the components will be omitted here.

According to the above-described semiconductor device and its fabricating method of the present embodiment, an etching process margin may be increased by forming an inclined structure under a memory layer to reduce an etching thickness when etching the memory layer. Accordingly, various defects caused by the etching process may be prevented and/or reduced.

FIG. 6 is view illustrating a memory layer according to an embodiment of the present disclosure. FIG. 6 shows an enlarged portion P1 of FIG. 3A.

Referring to FIG. 6, the memory layer 130 may include an MTJ (Magnetic Tunnel Junction) structure including a pinned layer 132 with its magnetization fixed at a predetermined direction, a tunnel barrier layer 134 formed of a non-magnetic layer that is sufficiently thin to allow spin polarized electrons to tunnel through, and a free layer 136 with a magnetization that can change or switch its direction in response to an interaction with spin polarized electrons or an applied magnetic field. With the above structure in the MTJ, the magnetization direction of the free layer 136 may have a changeable magnetization direction that is either in the same direction of, or in the opposite direction of, the fixed magnetization direction of the pinned layer 132, this providing two different magnetization states for storing different data according to the magnetization direction of the free layer 136. The change in the magnetization direction in the free layer 136 may be due to spin transfer torque. The free layer 136 may have a magnetization direction that is substantially perpendicular to the surface of the free layer 136. For example, the magnetization direction of the free layer 136 may change between a top-to-bottom direction and a bottom-to-top direction. However, the present disclosure is not limited thereto, and the free layer 136 may have a magnetization direction substantially parallel to the surface of the free layer 136. The magnetization direction of the pinned layer 132 may be contrasted with that of the free layer 136 by having a fixed magnetization direction. If the free layer 136 has a magnetization direction substantially perpendicular to the surface of the free layer 136, the pinned layer 132 may also have a magnetization direction substantially perpendicular to the surface of the pinned layer 132. For example, the magnetization direction of the pinned layer 132 may be fixed from bottom to top or from top to bottom. However, the present disclosure is not limited thereto, and when the free layer 136 has a magnetization direction substantially parallel to the surface of the free layer 136, the pinned layer 132 may also have a magnetization direction substantially parallel to the surface of the pinned layer 132. The tunnel barrier layer 134 may enable tunneling of electrons between the free layer 136 and the pinned layer 132 according to a voltage or current applied through the upper and lower ends of the MJT structure, thereby changing the magnetization direction of the free layer 136. Each of the free layer 136 and the pinned layer 132 may have a single-layer structure or a multi-layer structure including a ferromagnetic material. As an example, each of the free layer 136 and the pinned layer 132 may include an alloy containing Fe, Ni, or Co as a main component. Alternatively, each of the free layer 136 and the pinned layer 132 may include a stacked structure such as Co/Pt or Co/Pd, or may include an alternating stacked structure of a magnetic material and a non-magnetic material. The tunnel barrier layer 134 may include an insulating oxide, such as MgO, CaO, SrO, TiO, VO, or NbO. In the MTJ structure described above, the magnetization direction of the free layer 136 may be changed according to the applied voltage or current, and thus, different data may be stored. When the magnetization directions of the free layer 136 and the pinned layer 132 are parallel to each other, the MTJ structure may be in a low resistance state, and the magnetization directions of the free layer 136 and the pinned layer 132 are antiparallel to each other, the MTJ structure may be in a high resistance state.

However, the memory layer 130 is not limited to the illustrated one, and may be variously modified. As an example, the memory layer 130 may further include various layers (not shown) for improving characteristics of the MTJ structure or reducing process difficulty, in addition to the free layer 136, the tunnel barrier layer 134, and the pinned layer 132 described above. In some implementations, the memory layer 130 may further include a selector layer (not shown) that controls access to the MTJ structure while connecting to the MTJ structure above or below the MTJ structure, in addition to the MTJ structure. A brief description of the selector layer is as follows.

The selector layer may function to control access to the memory layer 130. In some implementations, the selector layer is a layer that is structured to be operated to function as a current control layer capable of controlling the current flow through the layer in response to an applied voltage and can be used in various semiconductor devices. In some implementations, the selector layer may have a threshold switching characteristic in which a current is blocked or hardly flows when the magnitude of the voltage supplied to the selector layer is less than a predetermined threshold voltage, and the passage of the current rapidly increases at a voltage equal to or higher than the threshold voltage. Thus, the selector layer may be turned on above the threshold voltage and turned off below the threshold voltage. This threshold value may be referred to as a threshold voltage, and the selector layer may be controlled to be in either a turned-on or “on” state to be electrically conductive or a turned-off or “off” state to be electrically less-conductive than the “on” state or electrically non-conductive depending on whether the applied voltage is above or below the threshold voltage. Thus, the selector layer exhibits different electrically conductive states to provide a switching operation to switch between the different electrically conductive states by controlling the applied voltage relative to the threshold voltage.

The selector layer may include at least one of a diode, an OTS (Ovonic Threshold Switching) material such as a chalcogenide-based material, an MIEC (Mixed Ionic Electronic Conducting) material such as a metal-containing chalcogenide-based material, an MIT (Metal Insulator Transition) material such as NbO₂ or VO₂, or a tunneling insulating material having a relatively wide band gap, such as SiO₂ or Al₂O₃. In some implementations, the selector layer may include an insulating material doped with dopants. The dopants may serve to create trap sites that trap conductive carriers migrating within the insulating material or provide a path for the captured conductive carriers to migrate again. When a voltage higher than the threshold voltage is applied to the selector layer including the insulating material doped with the dopants, the conductive carriers move through the trap sites, thereby realizing an on state in which current flows through the selector layer. When the voltage is reduced to a voltage less than the threshold voltage, an off state in which conductive carriers do not move and current does not flow may be implemented.

FIG. 7 is a view illustrating a memory layer according to another embodiment of the present disclosure. FIG. 7 shows an enlarged portion P1 of FIG. 3A.

Referring to FIG. 7, the memory layer 130 may include a first electrode layer 131, a variable resistance layer 133, and a second electrode layer 135.

Each of the first electrode layer 131 and the second electrode layer 135 may include various conductive materials, such as a metal, an alloy, or a conductive metal compound. Alternatively, each of the first electrode layer 131 and the second electrode layer 135 may include carbon.

The variable resistance layer 133 may store different data by switching between different resistance states according to a voltage or current applied through the first electrode layer 131 and the second electrode layer 135. The variable resistance layer 133 may include a material used in RRAM, for example, a metal oxide such as a transition metal oxide or a perovskite-based material. In this case, the resistance state of the variable resistance layer 133 may be switched between a low resistance state and a high resistance state by creation or disappearance of a conductive path in the metal oxide. The conductive path may be formed by metal ions or oxygen vacancies. Alternatively, the variable resistance layer 133 may include a material used in PRAM, for example, a phase change material such as a chalcogenide-based material. In this case, the resistance state of the variable resistance layer 133 may be switched between a low resistance state and a high resistance state depending on whether the phase change material has a crystalline state or an amorphous state.

However, the memory layer 130 is not limited to the illustrated one and may be variously modified. As an example, the memory layer 130 may further include various layers (not shown) for improving characteristics or reducing process difficulty. Alternatively, the memory layer 130 may further include a selector layer (not shown) connected to the first electrode layer 131 or the second electrode layer 135.

According to the above embodiments of the present disclosure, it may be possible to prevent and/or reduce defects due to the etching process by increasing the etching process margin.

Although various embodiments have been described for illustrative purposes, it will be apparent to those skilled in the art that various changes and modifications may be made without departing from the spirit and scope of the present teachings as defined in the following claims.

What is claimed is:

1. A semiconductor device, comprising:
a substrate;
a first contact plug disposed over the substrate;
two or more insulating patterns disposed on a side surface of the first contact plug and disposed sequentially along a direction away from the first contact plug; and
a memory pattern disposed over the first contact plug and connected to the first contact plug,
wherein an upper surface of the first contact plug and upper surfaces of the insulating patterns form an inclined surface whose height decreases as a distance from a center of the first contact plug increases,
the inclined surface includes a first inclined surface disposed on a first side of the center of the first contact plug and a second inclined surface disposed on second side of the center of the first contact plug, the second side opposite to the first side, and
the memory pattern has a lower surface in contact with the first inclined surface.

2. The semiconductor device according to claim 1, wherein the memory pattern has a side surface in contact with a portion of the second inclined surface.

3. The semiconductor device according to claim 2, wherein a remaining portion of the second inclined surface, except for the portion of the second inclined surface, does not contact the memory pattern.

4. The semiconductor device according to claim 1, further comprising:
a second contact plug disposed over the memory pattern and connected to the memory pattern.

5. The semiconductor device according to claim 4, wherein, in a plan view, the second contact plug is disposed spaced apart from the first contact plug.

6. The semiconductor device according to claim 4, wherein the memory pattern has an upper surface parallel to the first inclined surface, and
a lower surface of the second contact plug is in contact with the upper surface of the memory pattern.

7. The semiconductor device according to claim 1, wherein the memory pattern has a constant thickness.

8. The semiconductor device according to claim 1, wherein the first contact plug exhibits an etch rate smaller than etch rates of the insulating patterns, and
the etch rates of the insulating pattern increase spatially from the first insulating pattern to other insulating patterns that are further away from the first contact plug.

9. The semiconductor device according to claim 1, wherein the memory pattern includes a magnetic tunnel junction structure including a tunnel barrier layer between two ferromagnetic layers.

10. The semiconductor device according to claim 1, wherein the first contact plug includes a plurality of first contact plugs arranged along a first direction, and
the first inclined surface and the second inclined surface are alternately and repeatedly arranged along the first direction.

11. The semiconductor device according to claim 1, wherein the first contact plug has a pillar shape.

12. A method for fabricating a semiconductor device, comprising:
forming a first contact plug and first to Nth insulating patterns (where N is a natural number of 2 or more) sequentially disposed from the first contact plug and surrounding a side surface of the first contact plug, where an upper surface of the first contact plug and upper surfaces of the first to Nth insulating patterns form an inclined surface whose height decreases as a distance from a center of the first contact plug increases, and the inclined surface includes a first inclined surface disposed on one side of the center of the first contact plug and a second inclined surface disposed on the other side of the center of the first contact plug;
forming a memory layer such that a portion of the memory layer has a first thickness over the first inclined surface and another portion of the memory layer has a second thickness smaller than the first thickness over the second inclined surface; and
removing the another portion of the memory layer having the second thickness and providing a memory pattern connected to the first contact plug over the first contact plug.

13. The method according to claim 12, wherein the forming of the memory layer is performed by an inclined deposition in a direction toward the first inclined surface.

14. The method according to claim 13, wherein the inclined deposition is performed by a PVD (physical vapor deposition) method.

15. The method according to claim 12, wherein the removing of the another portion of the memory layer is performed by an inclined etching in a direction toward the second inclined surface.

16. The method according to claim 15, wherein the inclined etching is performed by an IBE (ion beam etching) method.

17. The method according to claim 12, wherein the forming of the first contact plug and the first to Nth insulating patterns includes:
forming an initial first contact plug having a pillar shape;
sequentially forming initial first to Nth insulating patterns to surround a surface of the initial first contact plug; and
performing a blanket etching process on the initial first contact plug and the initial first to Nth insulating patterns.

18. The method according to claim 17, wherein an etch rate of the initial first contact plug is smaller than an etch rate of the initial first insulating pattern, and
an etch rate of an initial t-th insulating pattern (where t is a natural number between 2 and N) among the initial first to Nth insulating patterns is greater than an etch rate of an initial (t−1)th insulating pattern.

19. The method according to claim 12, further comprising:
forming an interlayer insulating layer covering the memory pattern, after the memory pattern is formed; and
forming a second contact plug penetrating the interlayer insulating layer and contacting an upper surface of the memory pattern.

20. The method according to claim 19, wherein, in a plan view, the second contact plug is formed to be spaced apart from the first contact plug.

21. The method according to claim 12, wherein the memory pattern includes a magnetic tunnel junction structure including a tunnel barrier layer between two ferromagnetic layers.
